(19) United States
(12) Patent Application Publication
(10) Pub. No.: US 2009/0212438 A1
(43) Pub. Date: Aug. 27, 2009

(54) INTEGRATED CIRCUIT DEVICE COMPRISING CONDUCTIVE VIAS AND METHOD OF MAKING THE SAME

(76) Inventors: Franz Kreupl, Munich (DE); Harry Hedler, Germering (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 12/037,403

(22) Filed: Feb. 26, 2008

(51) Int. Cl. H01L 23/522; H01L 21/768

(52) U.S. Cl. 257/773; 257/777; 438/667; 257/E23.145; 257/E21.586

(57) ABSTRACT

A semiconductor substrate for an integrated circuit device comprises at least one insulating substrate region being formed of a cohesive insulating material. The insulating substrate region includes at least two conductive vias extending at least between a first surface and a second surface of the insulating substrate region.

### BACKGROUND OF THE INVENTION

The development of integrated circuit devices is driven by the trends of ever-increasing performance in conjunction with miniaturization of the feature sizes. One approach to facilitate these trends is the three-dimensional integration of integrated circuits. In this technology, semiconductor chips comprising circuit components, also referred to as “dice”, are arranged on top of each other and are electrically connected, thereby forming a “chip stack”. In order to establish electrical connections between chips in a chip stack arrangement, the semiconductor substrates of the chips are provided with conductive vias.

Conductive vias configured and fabricated according to conventional methods may cause a relatively high input capacitance of the electrical pathway, whereby electrical signals applied to and transferred by means of the conductive vias may be affected. A high input capacitance is further associated with a high energy consumption when operating the integrated circuits. Moreover, the number of chips to be arranged on top of each other in a chip stack is limited, since the connection of conductive vias in a chip stack represents a parallel connection of the input capacitances, in this way summing up the respective capacitances.

### BRIEF DESCRIPTION OF THE DRAWINGS

FIG. 1 shows a schematic perspective view of an integrated circuit comprising conductive vias;

FIG. 2 shows a schematic perspective view of another integrated circuit;

FIG. 3 shows a plan view of conductive vias arranged in a rectangular array;

FIG. 4 shows a plan view of conductive vias arranged in a hexagonal array;

FIG. 5 shows a schematic perspective view of an integrated circuit comprising conductive vias arranged in a hexagonal array;

FIGS. 6 and 7 show plan views of insulating substrate regions including conductive vias;

FIGS. 8 and 9 show schematic sectional views of substrates comprising an insulating substrate region;

FIGS. 10 to 13 show schematic perspective views of a substrate for illustrating steps of a method for fabricating an integrated circuit device comprising conductive vias;

FIGS. 14 to 22 show schematic sectional views of the substrate for illustrating further details of the aforementioned fabrication method;

FIG. 23 shows a schematic perspective view of a chip stack;

FIGS. 24 to 34 show schematic sectional views of a substrate for illustrating steps of alternative methods for fabricating an integrated circuit device;

FIGS. 35 and 36 show schematic sectional views of integrated circuit devices according to alternative implementations; and

FIGS. 37 to 42 show schematic sectional views of a substrate for illustrating steps of yet another method for fabricating an integrated circuit device.

Various features of implementations will become clear from the following description, taking in conjunction with the accompanying drawings. It is to be noted, however, that the accompanying drawings illustrate only typical implementations and are, therefore, not to be considered limiting of the scope of the invention. The present invention may admit other equally effective implementations.

### DETAILED DESCRIPTION OF THE PREFERRED EMBODIMENT

The implementations described in the following relate to integrated circuit devices comprising semiconductor substrates with conductive vias, and to methods of making the same. The integrated circuit devices may feature a low input capacitance.

A conventional conductive via typically includes a hole formed through the substrate, an insulating lining at the sidewall, and a conductive element which passes through the opening. The insulating lining, which is a dielectric layer comprising for example silicon dioxide or silicon nitride, isolates the conductive element from the surrounding (semi)conducting substrate material. This structure represents a capacitor, wherein the conductive element and the surrounding substrate constitute the electrodes of the capacitor. The capacitance value is roughly given by

C=k*A/d,

wherein k is the k-value and d is the thickness of the dielectric layer, and A is the peripheral area of the conductive via. The conductive vias, which are also referred to as “through silicon via” (TSV), are through connections passing completely through a substrate from an upper to a lower substrate surface. In a chip stack, conductive vias of chips that are superimposed relative to one another are electrically connected, e.g. by means of solder connections.

The embodiments described in the following relate to a semiconductor substrate comprising at least two conductive vias and to an integrated circuit device comprising one or a plurality of such semiconductor substrates. The implementations also relate to a method of making an integrated circuit device.

One embodiment includes a semiconductor substrate comprising at least one insulating substrate region being formed of a cohesive insulating material. The insulating substrate region includes at least two conductive vias extending at least between a first surface and a second surface of the insulating substrate region.

Another embodiment includes an integrated circuit device comprising a semiconductor substrate and a circuit component formed on the semiconductor substrate. The semiconductor substrate comprises at least one insulating substrate region being formed of a cohesive insulating material. The insulating substrate region includes at least two conductive vias extending at least between a first surface and a second surface of the insulating substrate region. The circuit component is electrically coupled to at least one of the conductive vias.

Another implementation includes an integrated circuit device comprising a stack of semiconductor substrates and circuit components formed on the semiconductor substrates. Each semiconductor substrate comprises at least one insulating substrate region being formed of a cohesive insulating material. The insulating substrate region of each semiconductor substrate includes at least two conductive vias extending at least between a first surface and a second surface of the insulating substrate region. At least one conductive via of each semiconductor substrate is electrically coupled to at least one conductive via of another semiconductor substrate of the stack of semiconductor substrates.

Another implementation includes a method of making an integrated circuit device. In the method, a semiconductor substrate having a first surface and a second surface is provided. At least two conductive vias and an insulating substrate region are formed, the conductive vias extending from the first surface to a first depth in the substrate and the insulating substrate region extending from the first surface to a second depth in the substrate. Here, the conductive vias at least partially penetrate the insulating substrate region. The method further includes thinning the semiconductor substrate at the second surface to expose the conductive vias and the insulating substrate region.

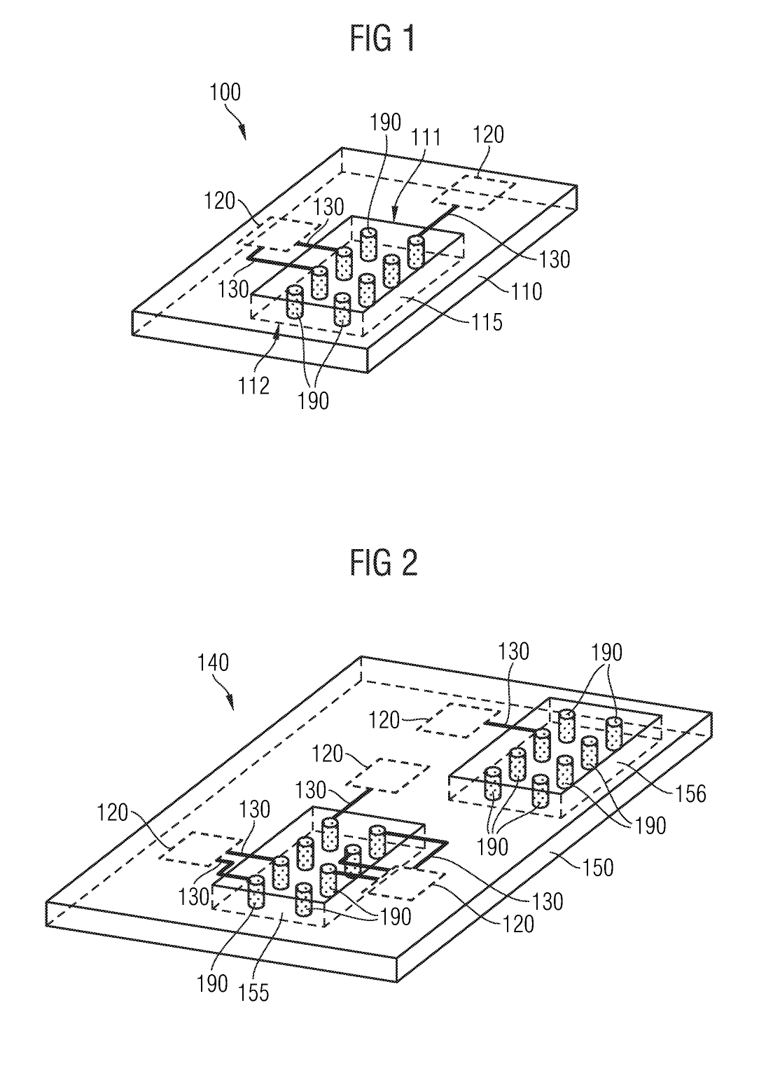

FIG. 1 shows a perspective transparent view of an integrated circuit 100 according to an implementation. The integrated circuit 100, also referred to as “chip”, includes a substrate 110 and circuit components 120 arranged on the substrate 110. The substrate 110, which comprises a semiconductor material such as for example silicon, has an upper and a lower substrate surface 111, 112 being substantially parallel to each other. The two surfaces 111, 112 are indicated as “first” surface 111 and “second” surface 112 in the following. The circuit components 120 may include active and passive electronic structures.

The substrate 110 further comprises a substrate region 115 being formed of a cohesive insulating or dielectric material, i.e. that the insulating material is provided in a connected manner. The substrate region 115 extends between the first and second surface 111, 112 of the substrate 110. In other words, a first and second surface of the substrate region 115 coincides with the two surfaces 111, 112. The substrate region 115 further comprises a number of conductive vias 190. The conductive vias 190 completely penetrate the substrate region 115 and extend at least between the first and second substrate surface 111, 112. The circuit components 120 are electrically coupled to at least one conductive via 190 of the number of conductive vias 190 by means of conductors 130.

The substrate region 115 including the number of conductive vias 190 is completely formed of the cohesive dielectric material, so that sidewalls of the conductive vias 190 are totally enclosed by the connected dielectric material between the first and second substrate surface 111, 112. The conductive vias 190 may therefore be referred to as “through dielectric vias” as opposed to “through silicon vias”. By means of the dielectric material, the conductive vias 190 are isolated from each other and from the (semi)conducting substrate material surrounding the substrate region 115. The term “dielectric material” as used herein is not limited to only one single dielectric, but also includes mixtures or layers of different dielectrics, as illustrated further below.

The configuration of the insulating substrate region 115 including the number of conductive vias 190 makes it possible to provide a relatively big distance between a conductive via 190 and the (semi)conducting substrate material of the substrate 110, whereby a parasitic capacitive coupling between the respective conductive via 190 and the substrate material may be relatively small and therefore negligible. Capacitive effects may substantially only occur between the conductive vias 190 themselves. As a consequence, the integrated circuit 100 may feature a reduced input capacitance, and thus a low energy consumption when operating the integrated circuit 100.

Various configurations are conceivable for the conductive vias 190. The conductive vias 190 may comprise a conductive material like e.g. doped poly Si or C. Furthermore, a metal like e.g. Cu, Al, Ni, Au and Ag may be applied. Further potential materials for the conductive vias 190 include e.g. a solder material or a conductive adhesive. The conductive vias 190 may comprise the mentioned materials individually or in the form of material mixes or alloys. It is also possible to provide layers of different materials in the conductive vias 190. In addition, the conductive vias 190 may comprise a barrier layer in order to prevent an out-diffusion of via material from the conductive vias 190 into the substrate region 115. Potential materials for a barrier layer include the materials TiW, Ti, TiN, Ta and TaN. A more detailed illustration of a an example of a conductive via 190 including layers of different materials is given below with respect to FIGS. 35 to 40.

With respect to the insulating material of the substrate region 115, various dielectrics may be used. An example is silicon dioxide or silicon nitride. Alternatively, polyimide or a polymer may be applied. Moreover, the substrate region 115 may comprise a spin-on glass (SOG). A spin-on glass, which is applied in liquid form and subsequently cured, may offer a low defect density, low cost, repeatability and high throughput. After cure, a spin-on glass film may exhibit a high uniformity and crack resistance, low stress, high thermal stability and adhesion.

An example of a potential spin-on glass is a silicate. Here, phosphosilicate glass (PSG) may be considered, which e.g. features an increased crack resistance and also adds sodium gettering abilities to the cured glass. Alternatively, a siloxane may be used as dielectric material for the substrate region 115. A siloxane may have the ability to fill gaps as small as 0.1 μm while effecting complete regional planarization. A potential siloxane is e.g. polysiloxane, which is a low-k material comprising a low dielectric constant. As a consequence, a parasitic input capacitance may be further reduced. A polysiloxane glass may for example have a dielectric constant which is smaller than 2.2. Apart from the mentioned materials, which are to be considered as examples, other dielectrics or low-k dielectrics may be applied. Furthermore, mixtures or layers of different dielectrics may be used to form the substrate region 115.

Instead of the integrated circuit 100 depicted in FIG. 1 comprising one dielectric substrate region 115 which includes conductive vias 190, implementations of an integrated circuit are conceivable which have a plurality of such substrate regions being separated from each other. As an example, FIG. 2 shows a perspective transparent view of another integrated circuit 140. The integrated circuit 140 comprises a substrate 150 and circuit components 120 arranged on the substrate 150. The substrate 150 comprises two separate dielectric substrate regions 155, 156, each substrate region 155, 156 including a number of conductive vias 190 and comprising a dielectric material enclosing sidewalls of the conductive vias 190. By means of conductors 130, the circuit components 120 are electrically coupled to conductive vias 190.

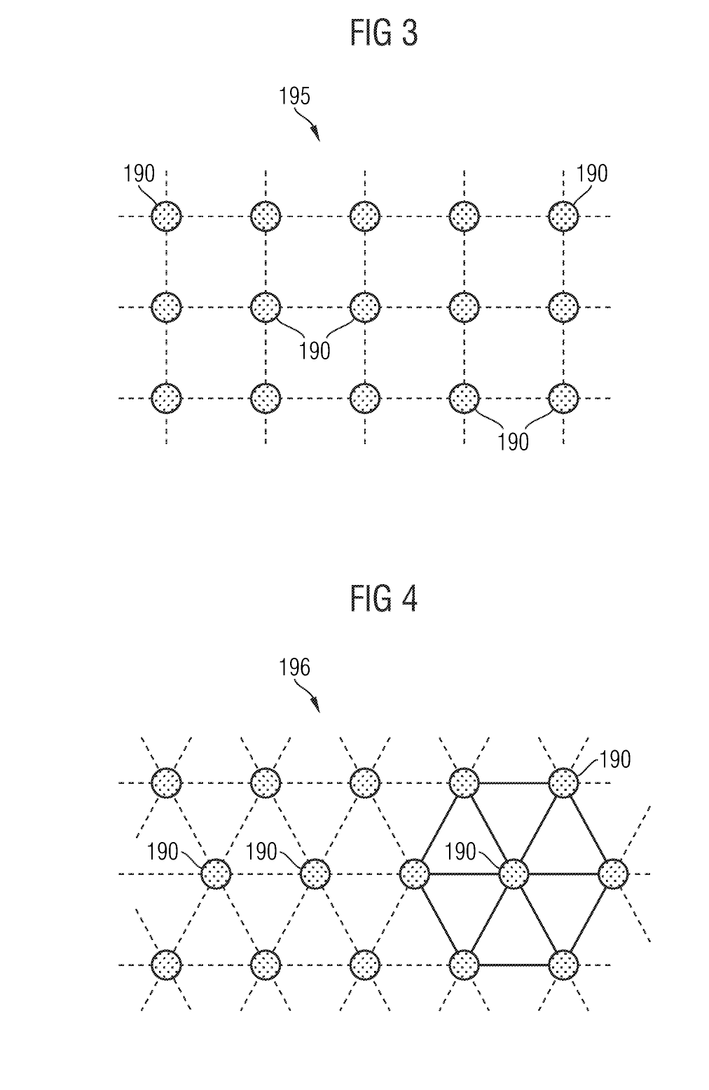

In the integrated circuits 100, 140 depicted in FIGS. 1 and 2, the conductive vias 190 are arranged in the form of a rectangular array. For way of illustration, such an arrangement of conductive vias 190 in form of a rectangular array 195 is depicted in the schematic plan view of FIG. 3. Alternatively, other arrangements of conductive vias 190 may be considered.

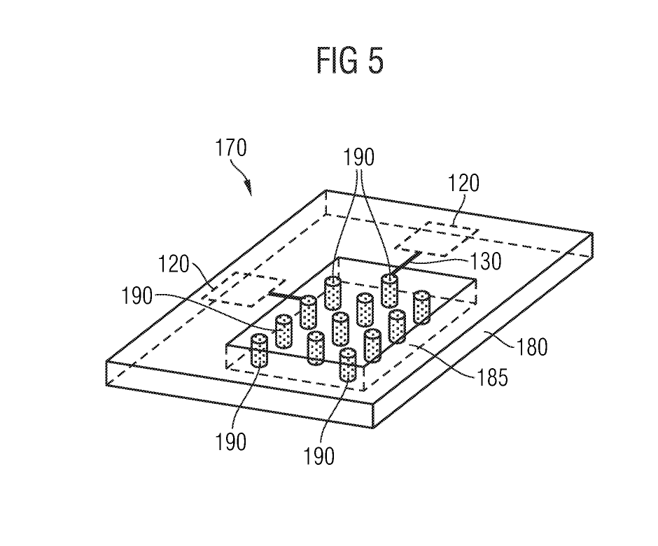

An example of another potential arrangement is shown in the plan view of FIG. 4. Here, conductive vias 190 being included in a dielectric substrate region of a semiconductor substrate (not shown) are arranged in a hexagonal array 196. In such an array 196, six conductive vias 190 are each located at vertices of a regular hexagon, respectively, the six conductive vias 190 surrounding a conductive via 190, as is indicated by means of a highlighted hexagon in FIG. 4. A hexagonal arrangement of conductive vias 190 makes it possible to reduce a capacitive coupling between the conductive vias 190 compared to a rectangular arrangement. An integrated circuit 170 having a configuration like this is depicted in FIG. 5. The integrated circuit 170 comprises a substrate 180 having a dielectric substrate region 185, the substrate region 185 including a number of conductive vias 190 which are arranged in a hexagonal array.

The dielectric substrate regions 115, 155, 156, 185 including conductive vias 190 depicted in the schematic FIGS. 1, 2 and 5 substantially have a cuboid shape with a rectangular base area at the first and second substrate surface. This geometry, however, represents an example and is therefore not limiting. Alternative forms and geometries of substrate regions including conductive vias are conceivable. For example, an insulating substrate region may be provided having at least one protruding portion or at least one notch.

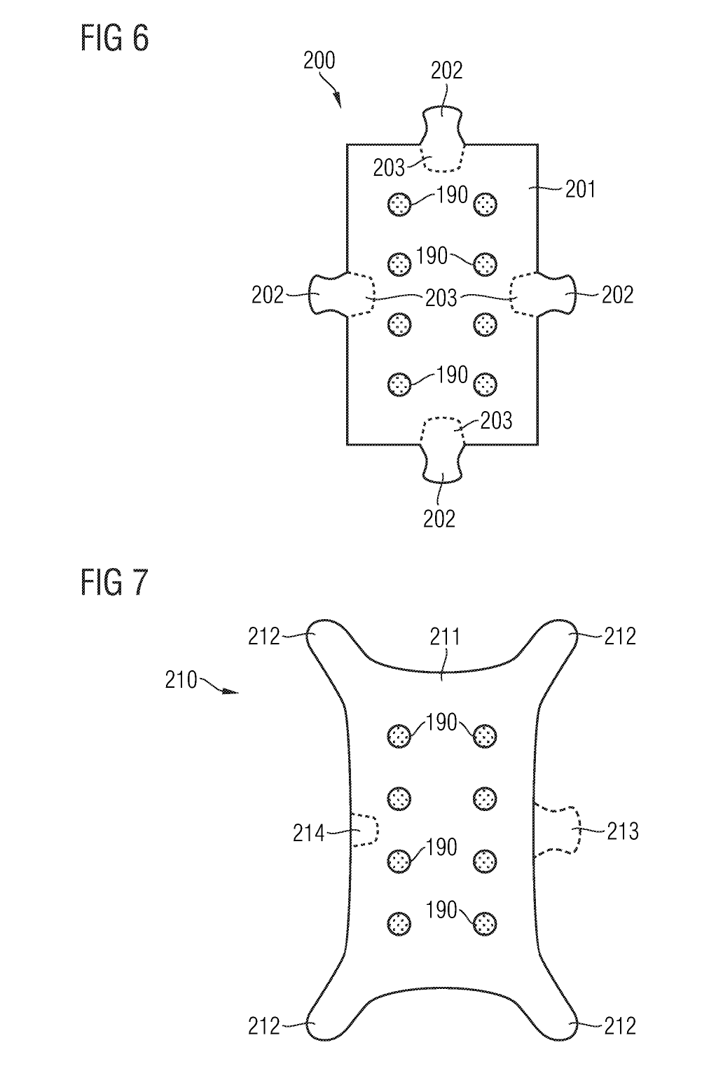

For way of illustration, FIG. 6 shows a schematic plan view of a dielectric substrate region 200. The substrate region 200 comprises a rectangular base 201 including a number of conductive vias 190, and protrusions 202 at the sides of the base 201. By means of the protrusions 202, an interlocking or form-locking connection is established between the substrate region 200 and the surrounding substrate material, thereby improving the mechanical fixation of the dielectric substrate region 200. In this way, for example a detaching of the substrate region 200 from the respective substrate due to mechanical tensions occurring in the substrate may be prevented. Alternatively, the substrate region 200 may also comprise notches 203 in the sides of the base 201, as indicated in FIG. 6. By means of the notches 203, a similar mechanical fixation between the substrate region 200 and substrate material enclosing the substrate region 200 may be achieved. Instead of the depicted four protrusions 202 and four notches 203, substrate regions may be provided having a different number of protrusions and notches. Moreover, substrate regions may be considered which comprise both at least one protrusion and at least one notch.

Another example of a dielectric substrate region 210 is shown in the schematic plan view of FIG. 7. The substrate region 210 comprises a substantially rectangular base 211 including a number of conductive vias 190, wherein corners 212 of the base 211 are configured as portions protruding into the surrounding substrate material. By means of this configuration, the mechanical fixation of the substrate region 210 in the respective semiconductor substrate may be increased, as well. Moreover, as indicated in FIG. 7, the substrate region 210 may optionally comprise one or more further protruding portions 213 and or notches 214 e.g. arranged at the side(s) of the base 211.

An increased mechanical fixation of a dielectric substrate region may also be achieved by forming lateral sidewalls of the substrate region in a way that the substrate region comprises different cross-sectional widths. In this way, it is possible to establish a form-locking connection between the dielectric substrate region and the surrounding substrate material, as well.

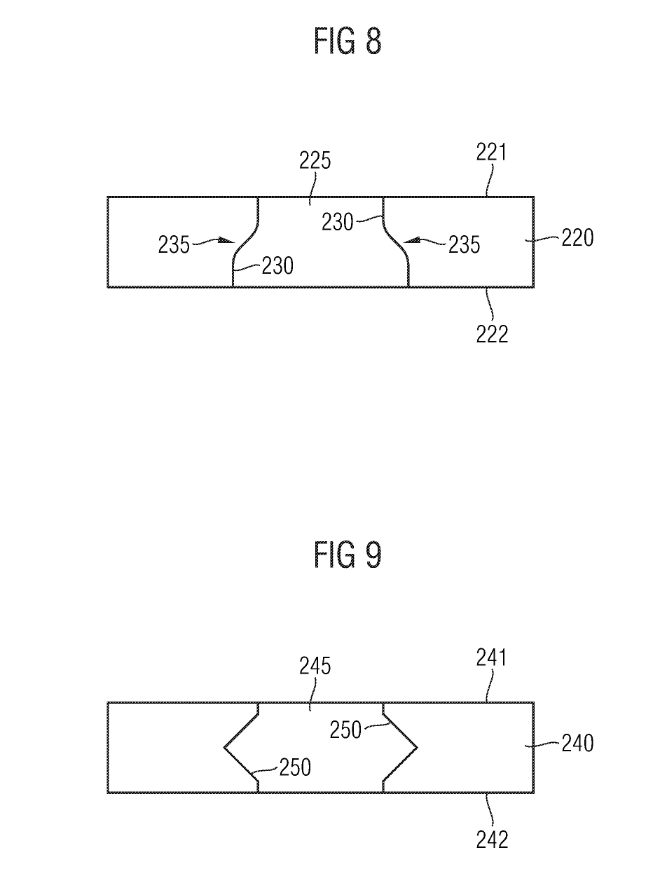

For way of illustration, FIG. 8 shows a schematic sectional view of a substrate 220 comprising a substrate region 225 being formed of a dielectric material. The substrate region 225 includes conductive vias passing through the substrate region 225 and extending at least between a first surface 221 and a second surface 222 of the substrate 220 (not shown). Each sidewall 230 of the substrate region 225 comprises a bending 235, whereby a widening of the substrate region 225 towards the second surface 222 is achieved, and the cross-sectional width of the substrate region 225 at the second surface 222 exceeds the cross-sectional width at the first surface 221. In this way, the mechanical fixation of the dielectric substrate region 225 may be increased.

Another example of a substrate 240 comprising a dielectric substrate region 245 including conductive vias (not shown) is depicted in the schematic sectional view of FIG. 9. The substrate region 245 comprises sidewalls 250, wherein portions thereof are oriented in an oblige manner with respect to a first surface 241 and a second surface 242 of the substrate 240, so that the cross-sectional width of the substrate region 225 in the middle exceeds the cross-sectional widths at the first and second surface 241, 242. This configuration provides a form-locking connection between the substrate region 225 and the surrounding substrate material, as well.

Apart from the examples of insulating substrate regions 225 and 245 depicted in FIGS. 8 and 9, further variations of a substrate region are conceivable which provide a form-locking connection between the substrate region and a surrounding substrate material. For example, sidewalls of substrate regions may be formed having more than two bendings or having a zigzag shape.

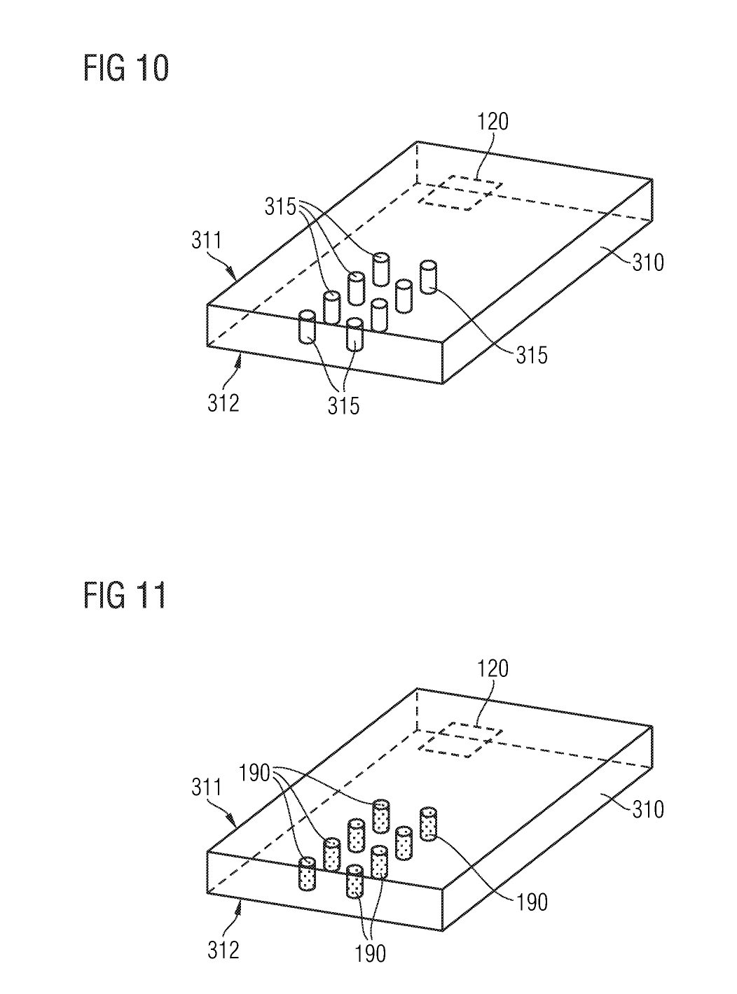

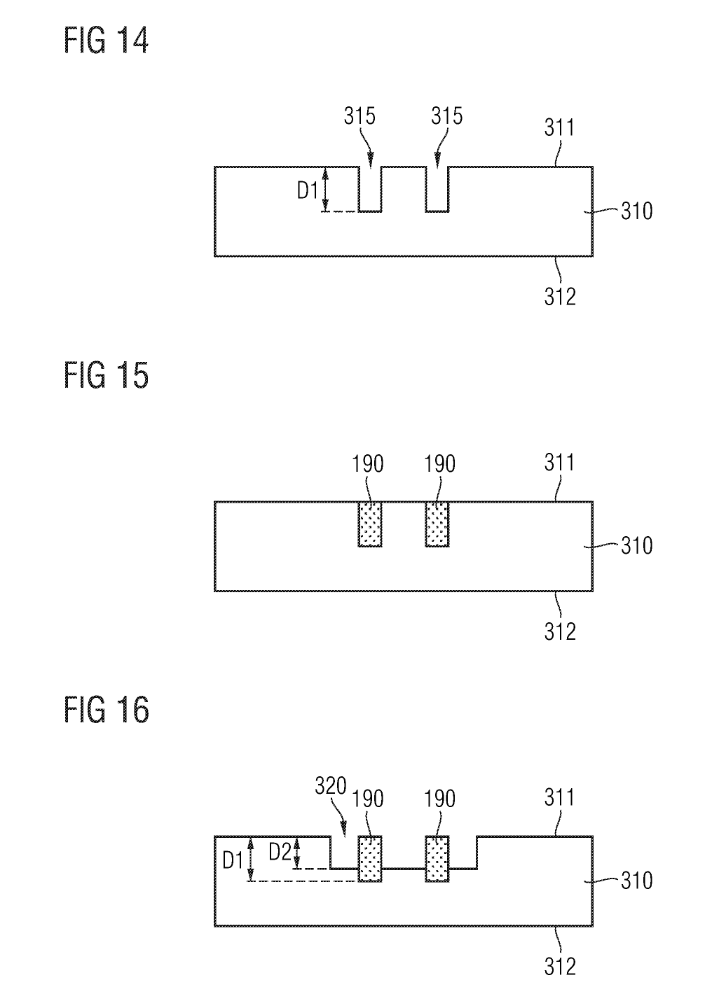

The following FIGS. 10 to 13 show perspective transparent views of a semiconductor substrate 310 for illustrating steps of a method for fabricating an integrated circuit device 300, 305. Corresponding lateral sectional views of the substrate 310 by means of which further details of the fabrication method become apparent are depicted in FIGS. 14 to 22.

As illustrated in FIGS. 10 and 14, the substrate 310 has a first surface 311 and a second surface 312 being substantially parallel to each other. The substrate 310, which comprises a semiconductor material such as for example silicon, may e.g. be a semiconductor wafer. Apart from silicon, the substrate 310 may comprise a different semiconductor material.

As further illustrated in FIGS. 10 and 14, via holes 315 are formed in the provided substrate 310. The via holes 315 extend from the first surface 311 to a depth D1 in the substrate 310. Various processes may be performed in order to fabricate the via holes 315. This includes e.g. the application of a laser. Alternatively, formation of the via holes 315 may be carried out by means of a dry etching process like e.g. deep reactive ion etching (DRIE). An example is the so-called Bosch process which may provide a high etch rate. In the dry etching process, the lateral structure of the via holes 315 is defined by means of one or several patterned masking layers (not shown). As an example, a photoresist layer may be used which is deposited on the first substrate surface 311 and structured by performing a lithographic method. The application of a hard mask layer comprising e.g. silicon nitride, carbon or aluminum on the substrate 310 is also conceivable, the hard mask layer being structured in an additional etching process by means of a masking photoresist layer. After forming the via holes 315, the masking layer(s) may be removed from the substrate 310.

The substrate 310 may be further provided with at least one circuit component 120, as indicated in FIG. 10. The circuit component 120 may be formed on or in the first substrate surface 311, or elsewhere in the substrate 310.

The circuit component comprises active and/or passive electronic structures. An example are transistors, diodes, resistors, capacitors, interconnect lines, etc., and portions thereof. The circuit component 120 may be fabricated before the formation of the via holes 315. Alternatively, formation of the circuit component 120 may also be carried out in a later process stage of the method or intermixed with the following method steps.

As shown in FIGS. 11 and 15, the via holes 315 are filled with a conductive material or a metallization, thus providing conductive vias 190. As described above with respect to the integrated circuit 100 of FIG. 1, various materials and configurations are conceivable for the conductive vias 190. This also applies to methods for filling up the via holes 315.

For example, a layer of a respective via material may be deposited on the first substrate surface 311 in a large-area fashion, thereby filling the via holes 315, and by subsequently carrying out a polishing process like CMP (chemical mechanical polishing), the deposited layer may be partially removed so that the layer material remains only in the via holes 315. Deposition of such a layer may e.g. be carried out by means of a CVD process (chemical vapor deposition) or a ALD process (atomic layer deposition). A sputtering process may also be applied. Deposition of a metal like e.g. Cu may be carried out by means of an electroplating process. In this case, a seed layer of the respective metal may be applied beforehand, e.g. by means of a sputtering process. After fabrication of the conductive vias 190, a top surface of the conductive vias 190 may flush with the first surface 311 of the substrate 310, as shown in FIG. 15.

Instead of one layer, several layers may be deposited one after another, so that the conductive vias 190 comprise several layers of different materials. In this case, formation of the conductive vias 190 may also include carrying out a wet chemistry etching process in order to structure a respective layer. It is also possible to form a patterned masking layer, e.g. a photoresist layer, before deposition of a via material, the patterned masking layer exposing the via holes 315. Details regarding an example of a fabrication of conductive vias 190 comprising different layers are given below with respect to the method depicted in FIGS. 35 to 40.

After fabrication of the conductive vias 190, substrate material is removed at the first substrate surface 311 in a substrate region including the conductive vias 190 (FIG. 16). In this way a recess 320 is provided and a portion of the conductive vias 190 and of the sidewalls of the conductive vias 190, respectively, is exposed. The substrate material is removed to a depth D2 relating to the first surface 311. The depth D2 is smaller than the depth D1 of the via holes 315 and thus of the height of the conductive vias 190.

Forming the recess 320 may include performing e.g. a deep reactive ion etching process such as a Bosch process. By means of a masking layer (not shown), e.g. a structured dry photoresist layer, the lateral dimensions of the recess 320 may be defined. Additionally, the conductive vias 190 may be masked and thus protected in the etching process by respective portions of the masking layer located on the conductive vias 190. After formation of the recess 320, the masking layer is removed.

It is possible to carry out etching of the recess 320 in a way that the etch isotropy is changed in the course of etching. This may e.g. be achieved by combining a dry etching process and a wet chemistry etching process. In this way, lateral sidewalls of the recess may be formed having a shape different from an upright shape (not shown). Moreover, the recess 320 may be fabricated having a structure which is different from a rectangular structure in a plan view (not shown), e.g. a structure similar to the substrate regions 200, 210 of FIGS. 6 and 7.

Furthermore, a cleaning step may be performed following the etching process in order to e.g. remove residues which remain after the etching process. A potential cleaning material which may be applied in such a step is for example ammonia.

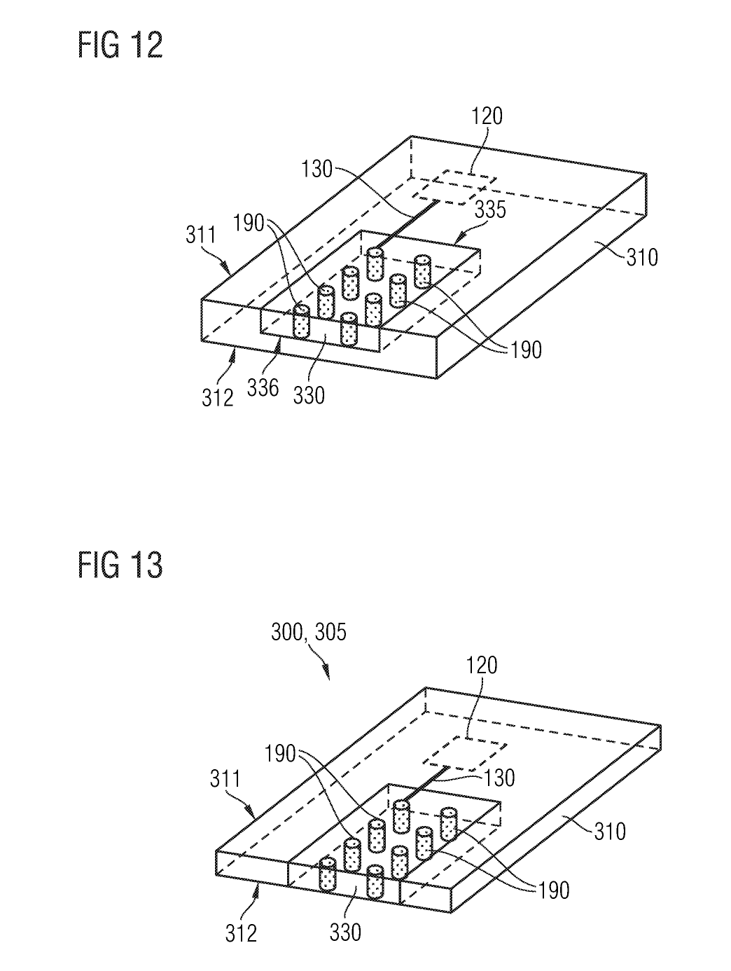

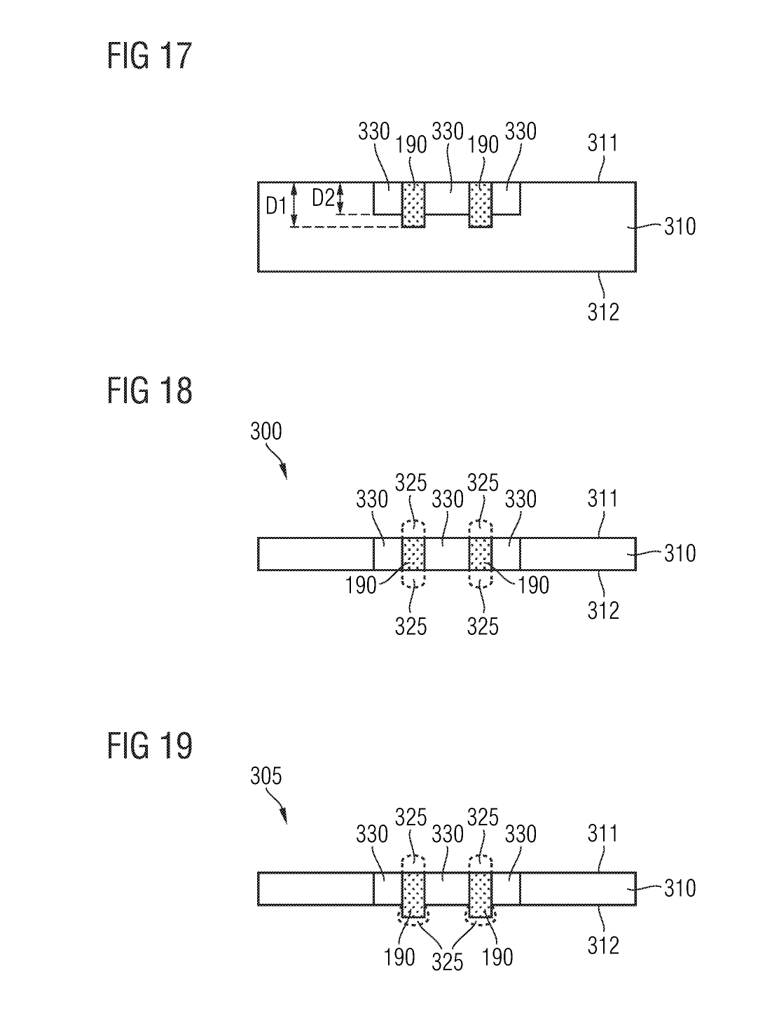

Subsequently, as shown in FIGS. 12 and 17, the recess 320 is filled with a dielectric material, which replaces the previously removed substrate material. In this way, a dielectric layer or substrate region 330 is provided which includes the conductive vias 190. The conductive vias 190 extend from the first surface 311 to the depth D1, and the dielectric substrate region 330 extends from the first surface 311 to the depth D2. Since the depth D1 exceeds the depth D2, the conductive vias 190 completely penetrate the dielectric substrate region 330 and further extend into the substrate material below the dielectric substrate region 330.

For fabricating the dielectric substrate region 330, a dielectric may be deposited on the substrate 310 in a large-area fashion, thereby filling the recess 320. By means of a subsequent polishing process like e.g. CMP, the dielectric may be partially removed in a manner that the dielectric remains only in the recess 320 and encloses sidewalls of the conductive vias 190. Silicon dioxide may be used as a material for the dielectric substrate region 330, and may be deposited e.g. by means of a CVD or an ALD process. Alternatively, a spin-on glass like e.g. the above mentioned phosphosilicate or (poly)siloxane may be applied, which is deposited on the substrate 310 in liquid form, subsequently cured and partially removed by means of a polishing process. Apart from these materials, other dielectrics or low-k dielectrics may be used to form the dielectric substrate region 330.

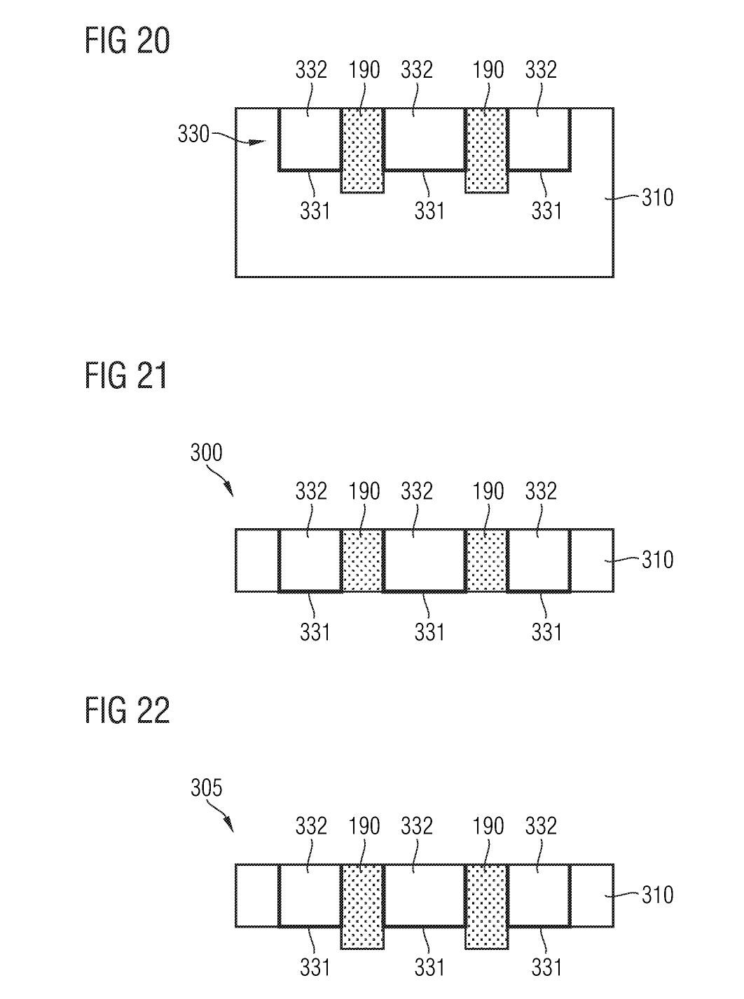

Furthermore, a combination of different dielectrics may be used to constitute the dielectric substrate region 330. An example is shown in the sectional view of FIG. 20. Here, a thin dielectric layer 331 comprising e.g. silicon dioxide or silicon nitride and having a thickness of e.g. 100 nm is at first formed in the recess 320, the layer 331 also covering sidewalls of the conductive vias 190. Subsequently, a layer 332 of a spin-on glass is applied on the dielectric layer 331 to fill up the recess 320. After carrying out a polishing process, the structure has a planar surface. In this way, the dielectric substrate region 330 comprises two “sublayers” 331, 332 having different dielectrics and being arranged on top of each other, wherein the glass layer 332 is partially enclosed by the dielectric layer 331. The application of the dielectric layer 331 makes it possible to obtain an increased mechanical stability, e.g. with regard to a potential brittleness of the spin-on glass 332 after curing.

As indicated in FIG. 12, provided that the circuit component 120 is already fabricated on the substrate 310, the circuit component 120 may be electrically coupled to at least one of the conductive vias 190. For this purpose, a conductor 130 connecting the circuit component 120 to the respective via 190 may be formed on the substrate 310. Fabricating the conductor 130 may e.g. be carried out by patterning the first surface 311 to form a respective recess extending between the circuit component 120 and the conductive via 190, and by subsequently filling up the recess with a conductive material. Alternatively, a conductive layer may be deposited on the first surface 311 and subsequently structured. In either case, fabrication of the conductor 130 and also of the circuit component 120 may be carried out in a later process stage, as well. It is also possible to fabricate a conductor 130 or a portion thereof before fabricating a circuit component 120 or a portion thereof, or to intermix the fabrication of a conductor 130 and of a circuit component 120, respectively.

The substrate 310 is furthermore thinned at the second surface 312 by removing respective substrate material. In this manner, the dielectric layer 330 and the conductive vias 190 are both exposed at the second surface 312 as shown in FIG. 13. In this way, an integrated circuit device 300, 305 having conductive vias 190 passing completely through the dielectric substrate region 330 is provided. For the case that the above-described formation of the recess 320 is carried out with a varying etch isotropy, a form-locking connection of the dielectric layer 330 in the substrate 310 may be realized (not shown). With regard to examples of a form-locking connection, reference is made to the dielectric substrate regions 225, 245 depicted in FIGS. 8 and 9. A form-locking connection may also be realized by fabricating the recess 320 having a structure which is different from a rectangular structure in a plan view (not shown).

The thinned substrate 310 and thus the integrated circuit device 300, 305 may further on constitute a (thinned) wafer. The wafer may subsequently be diced in order to produce a singulated integrated circuit or semiconductor chip 300, 305. Alternatively, dicing for the purpose of producing an integrated circuit 300, 305 may be performed at the same time as the thinning process. In this case, respective dicing recesses or lines are formed in the substrate 310, e.g. simultaneously with formation of the via holes 315 or of the recess 320.

The thinning step to expose the conductive vias 190 and the dielectric substrate region 320 may for example be performed by means of a polishing process like e.g. CMP. In the polishing process, a portion of the conductive vias 190 may be removed, and the polishing step may be stopped as soon as the dielectric substrate region 330 is exposed. The thus provided integrated circuit device 300 includes conductive vias 190, which flush with the second substrate surface 312 as shown in FIG. 18. Therefore, the conductive vias 190 have no protruding portions at the second surface 312. Provided that the dielectric substrate region 330 is fabricated having two dielectric sublayers 331, 332, the sublayer 331 may act as a polishing stop layer, as illustrated in FIG. 21.

Thinning the substrate 310 in order to expose the dielectric substrate region 330 and the conductive vias 190 at the second substrate surface 312 may alternatively be performed by means of a plasma etching process. In this process, a reactive etching plasma is applied to the second surface 312 of the substrate 310. The thus fabricated integrated circuit device 305 may comprise conductive vias 190, the conductive vias 190 having portions protruding from the second substrate surface 312, as shown in FIG. 19. In this implementation, the high selectivity of the plasma etch towards the substrate material compared to the material(s) of the conductive vias 190 is utilized. As illustrated in FIG. 22, provided that the substrate region 330 is fabricated having two dielectric sublayers 331, 332, the sublayer 331 may act as an etch stop layer.

The integrated circuit devices 300, 305 may optionally be provided with metallic bumps 325 comprising e.g. a solder material or a conductive adhesive on the conductive vias 190 on the first surface 311 and/or the second surface 312 of the substrate 310, as depicted in FIGS. 18 and 19. In this way, after a singulation step, a number of integrated circuits 300, 305 may be stacked on top of and electrically connected to each other.

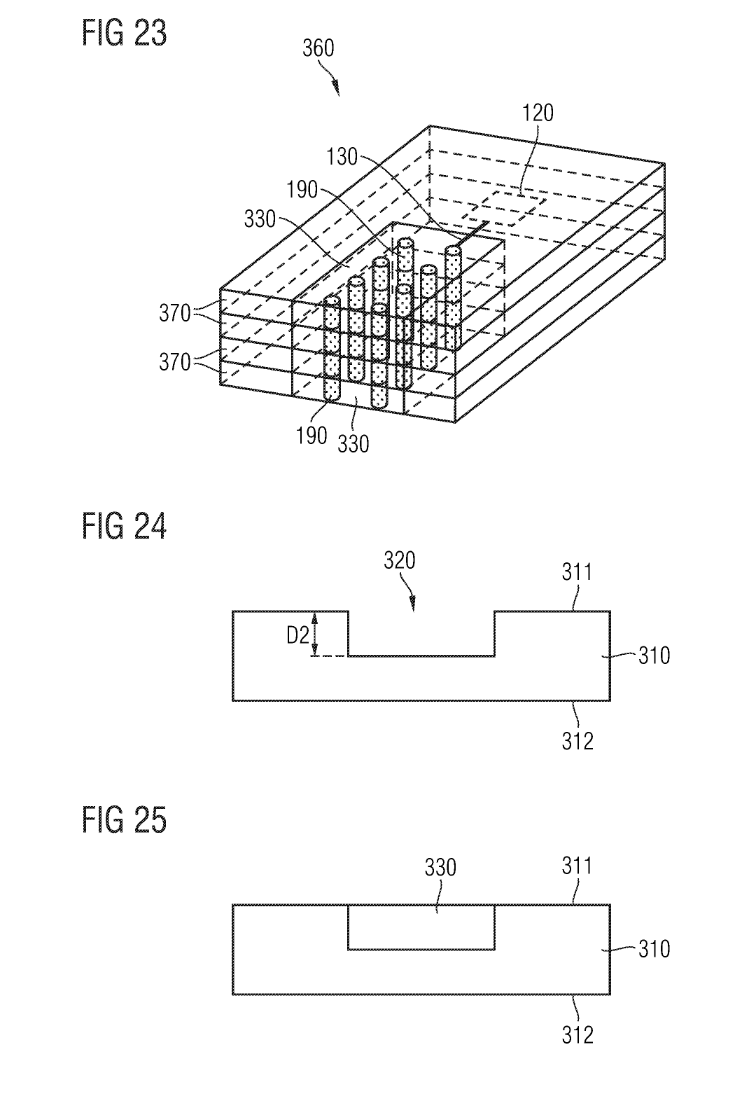

For way of illustration, FIG. 23 shows a chip stack 360 comprising a number of semiconductor chips 370 being arranged on top of each other. Each chip 370 comprises a dielectric substrate region 330 extending between a first and second substrate surface, the dielectric substrate region 330 including a number of conductive vias 190. Conductive vias 190 of superimposed chips 370 may be electrically coupled to each other, e.g. by means of the above mentioned metallic bumps 325. In the chip stack 360, a relatively high number of chips 370 may be arranged on top of and electrically connected to each other, since the provision of the dielectric substrate regions 330 including the conductive vias 190 makes it possible to achieve a low input capacitance.

In the method described with respect to FIGS. 10 to 22, the conductive vias 190 are formed prior to forming the dielectric substrate region 330. In this way, high etch rates of an etching process such as the Bosch process in the substrate material may be utilized when fabricating via holes 315. In alternative methods for fabricating an integrated circuit device 340, 345, 350, which are illustrated with reference to the following FIGS. 24 to 34, this sequence is reversed. With respect to corresponding process steps as well as to further details relating e.g. to the applied materials, reference is made to the above information with regard to the method described in conjunction with FIGS. 10 to 22.

An alternative method for fabricating an integrated circuit device 340 is shown in FIGS. 24 to 28. In a first step, a recess 320 is formed in a provided substrate 310 extending from a first surface 311 to a depth D2 (FIG. 24). The recess 320 is filled with a dielectric material, thereby providing a dielectric layer or substrate region 330 (FIG. 25).

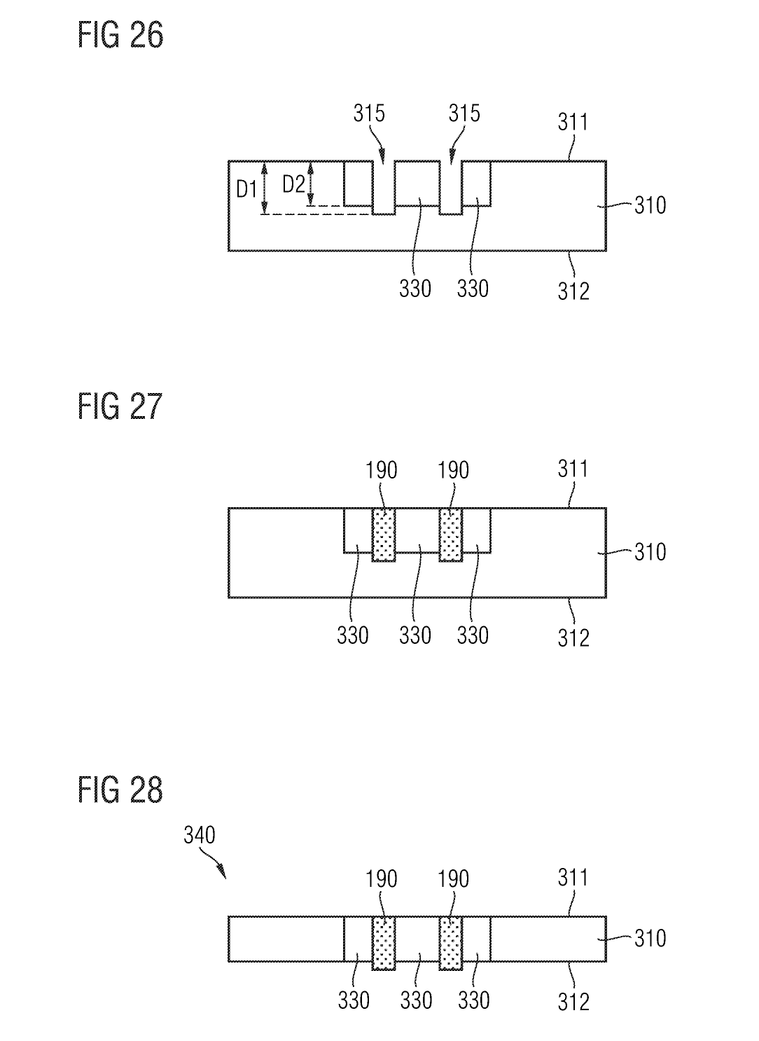

Subsequently, via holes 315 are formed for the later conductive vias 190 (FIG. 26). The via holes 315 extend from the first surface 311 to a depth D1 which exceeds the depth D2. Therefore, the via holes 315 completely pass through the dielectric layer 330 and also extend into the substrate material below the dielectric layer 330. The same applies to conductive vias 190, which are subsequently formed by filling the via holes 315 with a via material (FIG. 27).

Afterwards, the substrate 310 is thinned at a second surface 312 in order to expose both the conductive vias 190 and the dielectric substrate region 330 (FIG. 28). This step is e.g. performed by means of a plasma etching process, so that the fabricated integrated circuit device 340 comprises conductive vias 190, the conductive vias 190 having portions protruding from the second substrate surface 312.

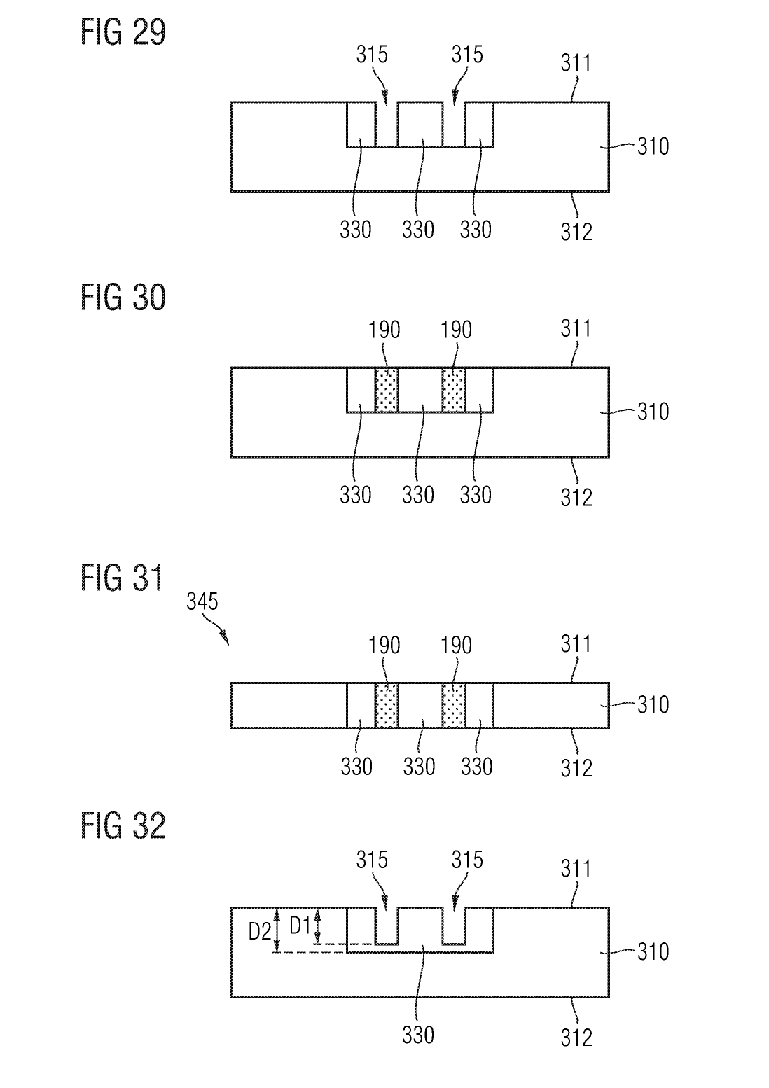

Alternatively, it is also possible to form the recess 320 and the via hole 315 in a manner that both the recess 320 and the via holes 315 extend from the first surface 311 to the same depth in the substrate 310. This also applies to the dielectric substrate region 330 after filling the recess 320 (FIG. 29), and to the conductive vias 190 after filling the via holes 315 (FIG. 30). After a subsequent thinning step, e.g. a polishing process carried out to expose the conductive vias 190 and the dielectric substrate region 330 at the second substrate surface 312, an integrated circuit device 345 is provided, wherein the conductive vias 190 extend from the first to the second substrate surface 311, 312 (FIG. 31).

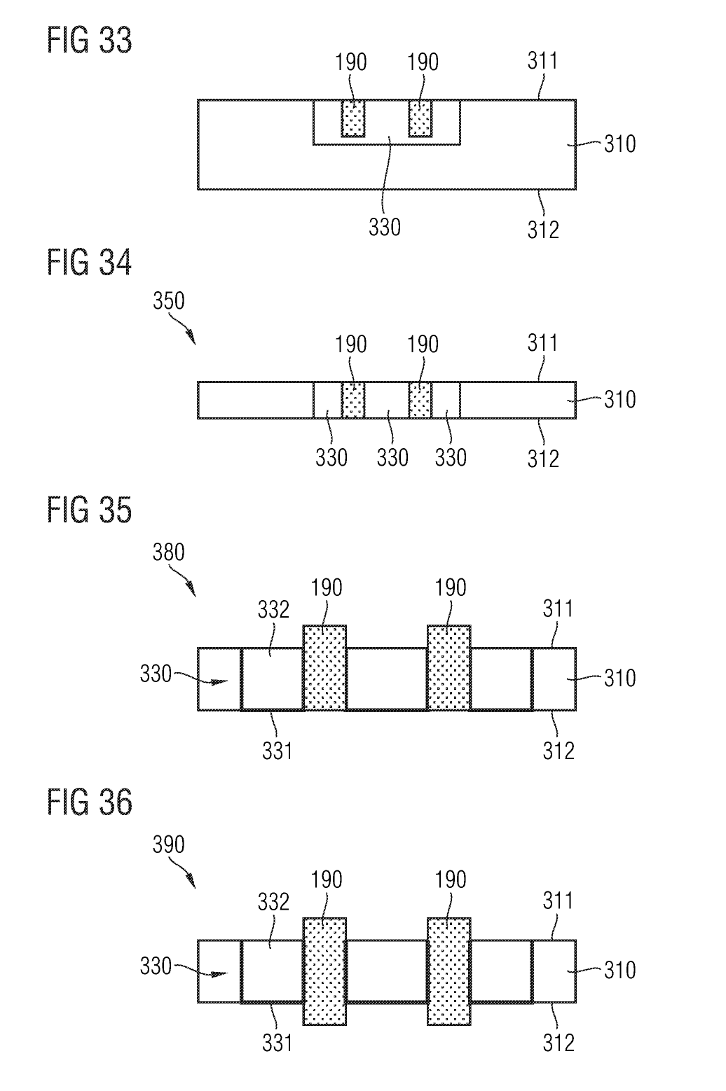

Another alternative method comprises forming the via holes 315 with a depth D1 which is smaller compared to the depth D2 of the recess 320 and thus of the height of the dielectric substrate region 330 (FIG. 32). As a consequence, the conductive vias 190 only partially penetrate the dielectric substrate region 330 (FIG. 33). After a subsequent thinning step, e.g. a polishing process, an integrated circuit 350 is provided comprising conductive vias 190, the conductive vias 190 again extending from the first to the second substrate surface 311, 312 (FIG. 34). In the polishing process, a portion of the dielectric substrate region 330 is removed so that both the conductive vias 190 and the substrate region 330 are exposed.

In the preceding FIGS. 19, 22 and 28, protruding portions of conductive vias 190 are formed at the second substrate surface 312. However, it is also possible to form conductive vias 190 in a way that portions thereof are protruding also from the first surface 311. For way of illustration, FIGS. 35 and 36 show schematic sectional views of integrated circuit devices 380, 390 according to alternative implementations. The integrated circuit device 380 depicted in FIG. 35 comprises conductive vias 190 passing through the dielectric substrate region 330 and having portions protruding from the first substrate surface 311. Conductive vias 190 of the integrated circuit device 390 of FIG. 36 have portions protruding both from the first and the second substrate surface 311, 312. In the integrated circuits 380 and 390, the dielectric substrate region 330 comprises two dielectrics or sublayers 331, 332, respectively. Alternatively, the dielectric substrate region 330 may also comprise only one dielectric.

Fabricating such protrusions of the conductive vias 190 at the first surface 311 may e.g. be carried out by means of an electroless deposition method, provided that the conductive vias 190 comprise a metal like e.g. Cu, Au, Ag, Ni etc. It is e.g. possible to subject the integrated circuit device 300 of FIG. 21 to an electroless deposition in order to fabricate the integrated circuit device 380 of FIG. 35, and to subject the integrated circuit device 305 of FIG. 22 to an electroless deposition in order to fabricate the integrated circuit device 390 of FIG. 36. Alternatively, the integrated circuit device 390 may be fabricated by subjecting the integrated circuit device 300 of FIG. 21 to electroless deposition in a manner that protrusions of conductive vias 190 are fabricated both at the first and second substrate surface 311, 312.

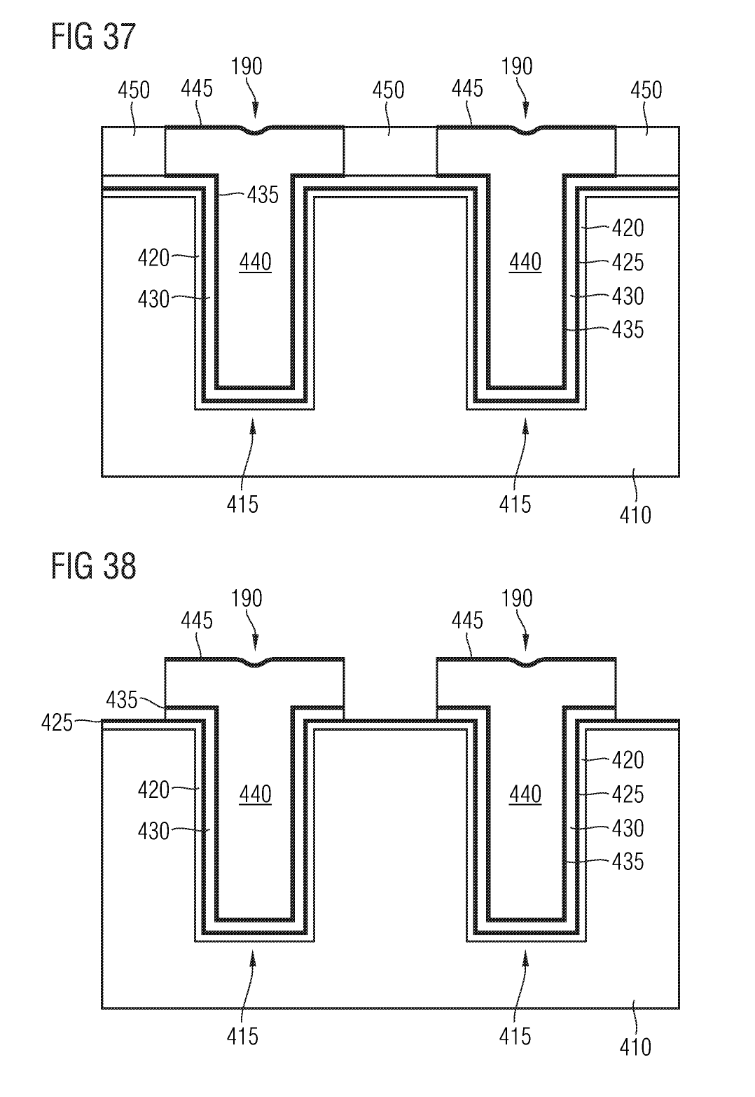

The following FIGS. 37 to 42 show schematic sectional views of a substrate 410 for illustrating steps of another method for fabricating an integrated circuit device 400, 401. In the method, conductive vias 190 comprising a number of different layers are formed.

As indicated in FIG. 37, openings or via holes 415 are formed in the provided substrate 410. For details regarding this method step, reference is made to the above information with regard to the method described in conjunction with FIGS. 10 to 22.

Subsequently, a dielectric layer 420 is formed on the substrate 410, which also covers sidewalls and the bottom of the via holes 415. The dielectric layer 420 may for example comprise silicon dioxide which is e.g. formed by thermal oxidation or deposited by means of a CVD process. Alternatively, the dielectric layer 420 may comprise silicon nitride, which may e.g. be applied by means of a CVD process. A thickness of the dielectric layer 420 may be in a range between for example 10 nm and 1 μm.

In a further step, a barrier layer 425 is deposited on the dielectric layer 420. The barrier layer 425, which for example comprises TiW, Ti/TiN or Ta/TaN, may have a thickness in a range of e.g. up to 200 nm. For fabricating the barrier layer 425, for example a sputtering process or a CVD process may be applied. By means of the previously formed dielectric layer 420, potential chemical reactions which may occur between the barrier layer 425 and the surrounding substrate material like e.g. a silicidation process may be prevented.

After application of the barrier layer 425, a metallic seed layer 430 is deposited on the barrier layer 425. The seed layer 430 comprises e.g. Cu and has a thickness which is sufficient to provide a continuous coverage in the via holes 415. For this purpose, the seed layer 430 may have a thickness in a range between for example 0.1 μm and 2 μm. The deposition of the seed layer 430 may e.g. be carried out by means of a sputtering process. Due to the barrier layer 425, an out-diffusion of metal of the seed layer 430 (and of further layers deposited in a later process stage) into the substrate 410 may be prevented.

Afterwards, a dry photoresist film or layer 450 is deposited on the substrate 410, i.e. on the seed layer 430, and subsequently patterned to expose the via holes 415. As indicated in FIG. 37, the photoresist layer 450 may be patterned in such a way that also a portion of the seed layer 430 extending laterally beyond the via holes 415 is uncovered.

Optionally, one or more metallic layers 435 are deposited on the seed layer 430, i.e. on the uncovered portion of the seed layer 430. For this purpose, an electroplating process may be performed. In this process, a cathode terminal of a power source may be placed in electrical contact with the seed layer 430 at the periphery of the substrate 410. It is for example possible to electroplate an Au layer having a thickness of e.g. 0.2 μm, and afterwards a Ni layer having a thickness of 1.0 μm. For reasons of clarity, only one layer 37 is depicted in FIG. 37 which may include several layers.

Subsequently, a metallic material 440 like e.g. Cu is deposited in order to completely fill up the via holes 415 and to provide conductive vias 190 which may protrude out of the via holes 415, as depicted in FIG. 37. This step may also be performed by means of an electroplating process. Optionally, a further metallic layer 445 comprising for example Ni is deposited on the top surface of the metallic layer 440 to a thickness of e.g. 0.5 μm. For this purpose, an electroplating process may be performed, as well.

Subsequently, the photoresist layer 450 is removed. Optionally, also the exposed portion of the seed layer 430 is removed as illustrated in FIG. 38. Removing the exposed portion of the seed layer 430 may be performed by means of a wet chemistry etching process, wherein the metallic layer 445 may act as a mask to protect the metallic material 440 in the vias 415. During the wet etch, a lateral etching of the seed layer 430 and of the metallic layer 440 may occur. Due to the fact that these layers 430, 440 extend laterally beyond the edges of the via openings 415, the layers 430, 440 are not removed over the via openings 415. Concerning implementations in which the masking metallic layer 445 is omitted, the wet etch may reduce the thickness of the metallic layer 440. However, the thickness of the metallic layer 440 is selected in such a way that in either case the top surface of the metallic layer 440 is at or extends above the dielectric layer 420 after the wet etch.

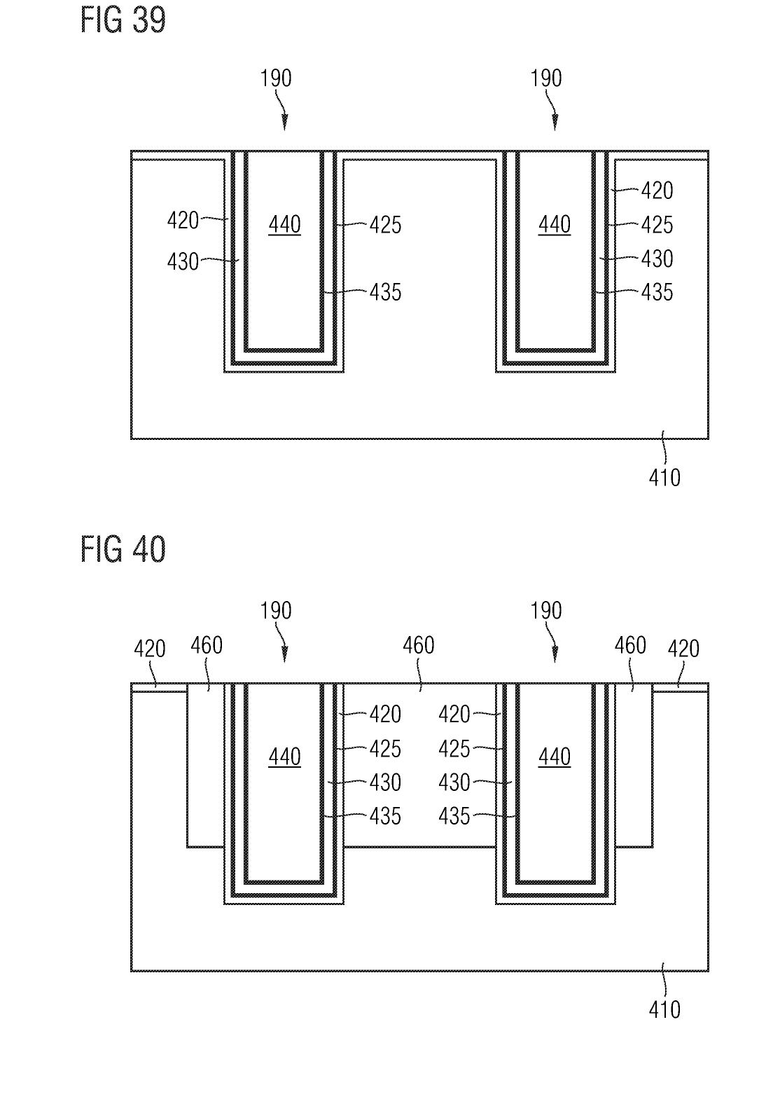

Subsequently, a polishing process like e.g. CMP is performed in order to provide a planer substrate surface, as illustrated in FIG. 39. The polishing process is stopped on the dielectric layer 420, which may act as a polishing stop layer. The polishing process may also be carried out in a case in which the above mentioned wet etching process is omitted.

In a next step, a dielectric layer or substrate region 460 is formed in the substrate 410, the dielectric substrate region 460 including the conductive vias 190 as illustrated in FIG. 40. The conductive vias 190 completely pass through the dielectric substrate region 460 and further extend into the substrate material underneath the dielectric substrate region 460. Formation of the dielectric substrate region 460 may be carried out by forming a respective recess in the substrate 410, filling the recess with a dielectric material and performing a polishing process to remove the dielectric material outside the recess (not shown).

Forming the recess includes forming a patterned masking layer, e.g. a dry photoresist layer, which defines the lateral dimensions of the recess and exposes a respective surface region, and which may have portions above the conductive vias 190 for protecting the same. Afterwards, the uncovered portion of the dielectric layer 420 may be removed at first by performing e.g. a wet or a dry etching process, thereby exposing the substrate material located underneath. Subsequently, a deep reactive ion etching process like the Bosch process may be performed in order to remove the exposed substrate material.

As a material for the dielectric substrate region 460 which is filled into the recess, e.g. a spin-on glass may be considered. With respect to further details regarding potential dielectrics for the substrate region 460 and the fabrication of the substrate region 460, reference is made to the above information with regard to the method described in conjunction with FIGS. 10 to 22.

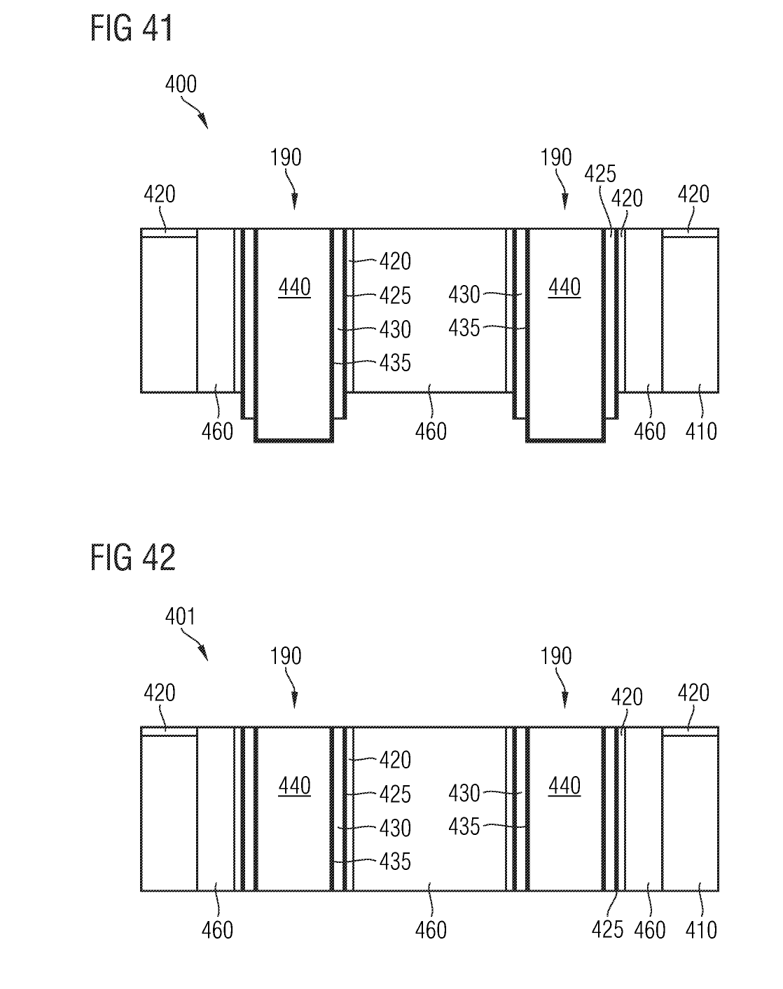

The substrate 410 is furthermore thinned from the back surface in order to expose the dielectric substrate region 460 and the conductive vias 190. Potential integrated circuit devices 400, 401 which are provided after this step are depicted in FIGS. 41 and 42. The integrated circuit devices 400, 401 comprise conductive vias 190 having different layers 420, 425, 430, 435, 440. Here, lateral sidewalls of the conductive vias are constituted by the dielectric layer 420.

Referring to the integrated circuit device 400 of FIG. 41, the thinning step may be performed by means of a plasma etching process. Here, e.g. CF4 may be applied as etching plasma. As a consequence, portions of the conductive vias 190 or of the different layers 425, 430, 435, 440 may protrude from the back surface of the substrate 410. The plasma etching process may be stopped when the dielectric substrate region 460 is exposed. Alternatively, referring to FIG. 42, a polishing process like e.g. CMP may be performed, whereby the integrated circuit device 401 may have a planar back surface, i.e. the conductive vias 190 have no protruding portions.

The implementations described in conjunction with the drawings are examples. Moreover, further implementations may be realized which comprise further modifications and combinations of the described integrated circuit devices and methods.

It is e.g. possible to fabricate a dielectric substrate region including conductive vias, the substrate region having—in a plan view—a base area and at least one protrusion (and/or at least one notch) as well as different cross-sectional widths. Such an implementation may e.g. be realized by combining geometries of the substrate regions of FIGS. 6, 7 and FIGS. 8, 9. Furthermore, instead of a rectangular array of via holes and conductive vias depicted in the methods and devices, a hexagonal array may be provided.

Moreover, the mentioned materials are to be considered as examples and not limiting, and may be replaced by other materials. This also applies to information given with respect to e.g. layer thicknesses.

The implementations of an integrated circuit device or chip may have a semiconductor substrate comprising an insulating or dielectric substrate region, the substrate region including at least two conductive vias which extend (at least) between a first surface and a second surface of the integrated substrate region. The first and second surface of the insulating substrate region may coincide with a first and second surface of the substrate, i.e. that the insulating substrate region is uncovered both at the first and second substrate surface. An example of such an integrated circuit is e.g. the integrated circuit 300, 305 of FIG. 13.

Alternatively, an integrated circuit may be considered, wherein an insulating substrate region including conductive vias comprises a first and second surface which do not both coincide with a first and second surface of the respective substrate. Such an integrated circuit may e.g. comprise a substrate similar to the substrate 310 of FIG. 12. Here, the first surface 311 of the substrate 310 coincides with a first surface 335 of the insulating substrate region 330. The second surface 312 of the substrate 310, however, does not coincide with a second surface 336 of the insulating substrate region 330, but is substantially parallel to the same, since the substrate region 330 is only uncovered at the first substrate surface 311. In such an implementation, the conductive vias 190 may extend (at least) between the first and second surface 335, 336 of the substrate region 330, as well. The conductive vias 190 may optionally have protruding portions at the second surface 336, i.e. also extend into the substrate material below the substrate region 330 and/or have protruding portions at the first surface 335.

The preceding description describes examples of implementations of the invention. The features disclosed therein and the claims and the drawings can, therefore, be useful for realizing the invention in its various implementations, both individually and in any combination. While the foregoing is directed to implementations of the invention, other and further implementations of this invention may be devised without departing from the basic scope of the invention, the scope of the present invention being determined by the claims that follow.

What is claimed is:

1. A semiconductor substrate, comprising:
a semiconductor portion defining an upper surface and a lower surface; and
at least one insulating substrate region defining a first surface and a second surface and being formed of a cohesive insulating material, wherein the at least one insulating substrate region is at least partially disposed between the upper surface and the lower surface and includes at least two conductive vias extending at least between the first surface and the second surface of the insulating substrate region.

2. The semiconductor substrate according to claim 1, wherein the upper surface and the lower surface are parallel to each other and parallel to the first surface and the second surface.

3. The semiconductor substrate according to claim 1, wherein the upper surface and the first surface are coplanar, and wherein the lower surface and the second surface are coplanar.

4. The semiconductor substrate according to claim 1, wherein the conductive vias are arranged in a hexagonal array.

5. The semiconductor substrate according to claim 1, wherein the conductive vias comprise portions protruding from the first and/or the second surface of the insulating substrate region.

6. The semiconductor substrate according to claim 1, wherein the conductive vias comprise a metal, an alloy, a solder and/or a conductive adhesive.

7. The semiconductor substrate according to claim 6, wherein the conductive vias further comprise a barrier layer which prevents an out-diffusion of via material from the conductive vias.

8. The semiconductor substrate according to claim 1, wherein the conductive vias comprise at least one of the following materials or combinations thereof: Cu, Al, Ni, Au, Ag, doped poly Si, C, TiW, Ti, TiN, Ta, TaN.

9. The semiconductor substrate according to claim 1, wherein the insulating substrate region comprises a protrusion and/or a notch in order to increase the mechanical fixation between the insulating substrate region and substrate material surrounding the insulating substrate region.

10. The semiconductor substrate according to claim 1, wherein the insulating material of the insulating substrate region comprises a low-k dielectric.

11. The semiconductor substrate according to claim 1, wherein the insulating material of the insulating substrate region comprises a spin-on glass.

12. The semiconductor substrate according to claim 1, wherein the insulating substrate region including the conductive vias comprises layers of different dielectrics arranged on top of each other.

13. The semiconductor substrate according to claim 1, wherein the insulating material of the insulating substrate region comprises one of the following dielectrics: silicon dioxide, silicate, phosphosilicate, siloxane, silicon nitride, polyimide, polymer.

14. An integrated circuit device, comprising:
a semiconductor substrate; and
a circuit component formed on the semiconductor substrate,
wherein the semiconductor substrate comprises a semiconductor portion defining an upper surface and a lower surface and at least one insulating substrate region defining a first surface and a second surface and being formed of a cohesive insulating material, wherein the at least one insulating substrate region is at least partially disposed between the upper surface and the lower surface and includes at least two conductive vias extending at least between the first surface and the second surface of the insulating substrate region, and
wherein the circuit component is electrically coupled to at least one of the conductive vias.

15. The integrated circuit device according to claim 14, wherein the conductive vias are arranged in a hexagonal array.

16. The integrated circuit device according to claim 14, wherein the insulating material of the insulating substrate region comprises a low-k dielectric.

17. The integrated circuit device according to claim 14, wherein the insulating material of the insulating substrate region comprises a spin-on glass.

18. An integrated circuit device, comprising:
a stack of semiconductor substrates; and
circuit components formed on the semiconductor substrates,
wherein each semiconductor substrate comprises a semiconductor portion defining an upper surface and a lower surface and at least one insulating substrate region defining a first surface and a second surface and being formed of a cohesive insulating material, wherein the at least one insulating substrate region is at least partially disposed between the upper surface and the lower surface and includes at least two conductive vias extending at least between the first surface and the second surface of the insulating substrate region, and
wherein at least one conductive via of each semiconductor substrate is electrically coupled to at least one conductive via of another semiconductor substrate of the stack of semiconductor substrates.

19. A method of making an integrated circuit device, comprising:
providing a semiconductor substrate having a first surface and a second surface;
forming at least two conductive vias and an insulating substrate region, the conductive vias extending from the first surface to a first depth in the substrate and the insulating substrate region extending from the first surface to a second depth in the substrate, wherein the conductive vias at least partially penetrate the insulating substrate region; and
thinning the semiconductor substrate at the second surface to expose the conductive vias and the insulating substrate region.

20. The method according to claim 19, further comprising:
forming a circuit component on the semiconductor substrate; and
electrically coupling the circuit component to at least one of the conductive vias.

21. The method according to claim 19, wherein the conductive vias are formed prior to forming the insulating substrate region, and wherein the first depth exceeds the second depth.

22. The method according to claim 19, wherein the conductive vias are arranged in a hexagonal array.

23. The method according to claim 19, wherein forming the insulating substrate region comprises:
removing substrate material at the first surface of the semiconductor substrate to provide a recess;
filling the recess with an insulating material; and
partially removing the insulating material in such a manner that the insulating material remains solely in the recess.

24. The method according to claim 23, wherein the insulating material comprises a low-k dielectric.

25. The method according to claim 23, wherein the insulating material comprises a spin-on glass.

26. The method according to claim 19, wherein thinning the semiconductor substrate comprises one of:
performing a plasma etching process; and
performing a polishing process.
